(19) United States
(12) Patent Application Publication
(10) Pub. No.: US 2026/0005515 A1
(43) Pub. Date: Jan. 1, 2026

(54) SYSTEMS AND METHODS FOR DISTANCE-BASED ASSIGNMENT OF METERS TO TRANSFORMERS

(71) Applicant: Aclara Technologies LLC, St. Louis, MO (US)

(72) Inventors: Raul Rodriguez, Bizkaia (ES); Iker Garcia, Bizkaia (ES); Jennifer Gonzalez, Cantabria (ES); Lakhsan Piyasinghe, St. Charles, MO (US); Nerea Jimeno Butrón, Bizkaia (ES)

(21) Appl. No.: 19/251,256

(22) Filed: Jun. 26, 2025

Related U.S. Application Data
(60) Provisional application No. 63/665,203, filed on Jun. 27, 2024.

(51) Int. Cl. H02J 3/00; G01D 4/00

(52) U.S. Cl. CPC H02J 3/007; G01D 4/002; G01D 2204/47; H02J 2203/10; H02J 2203/20

(57) ABSTRACT

A utility distribution including a number of electrical meters, a number of transformers, and a central utility controller. The central utility controller is configured to receive an initial map of the number of electrical meters to their respective transformers, receive data from the number of electrical meters, and execute an initial adjustment to the initial map by verifying that each electrical meter and transformer complies with a predefined constraint. The central utility controller is further configured to randomly analyze a first meter of the number of electrical meters to determine a first likely connection to a first transformer of the number of transformers and update a connection of the first meter to the first transformer in the initial map based on the determined first likely connection.

### CROSS-REFERENCE TO RELATED APPLICATIONS

The present application is related to and claims benefit under 35 U.S.C. § 119 (e) from U.S. Provisional Patent Application Ser. No. 63/665,203, filed Jun. 27, 2024, the entire contents of which is incorporated herein by reference

### FIELD

The embodiments disclosed herein relate to mapping electrical meters to transformers within a power distribution network.

### BACKGROUND

Generally, utility providers, such as electrical providers, rely on information from field personnel to map or otherwise record what transformer a given meter (e.g., a residential, commercial, industrial, etc. power meter) is connected to. However, studies have shown that these records are not 100% accurate, and, in fact, are generally only accurate to about 80%-90%. This can present issues when identifying issues during a power outage, or during required maintenance.

A system for automatically determining and/or verifying the meter to transformer relationship within a utility system would therefore be advantageous.

### SUMMARY

In one embodiment, a utility distribution is described, including a number of electrical meters, a number of transformers, and a central utility controller. The central utility controller is configured to receive an initial map of the number of electrical meters to their respective transformers, receive data from the number of electrical meters, and execute an initial adjustment to the initial map by verifying that each electrical meter and transformer complies with a predefined constraint. The central utility controller is further configured to randomly analyze a first meter of the number of electrical meters to determine a first likely connection to a first transformer of the number of transformers and update a connection of the first meter to the first transformer in the initial map based on the determined first likely connection.

In one aspect, the central utility controller is further configured to execute one or more similarity measures to determine the first likely connection.

In another aspect, the central utility controller is further configured to iteratively randomly analyze an n+1 meter of the plurality of electrical meters to determine an n+1 likely connection to an n+1 transformer of the plurality of transformers, and update the connection of the n+1 meter to the n+1 transformer based on the determined n+1 likely connection.

In another aspect, finalizing the iterative random analysis in response to all n+1 meters being iteratively analyzed.

In another aspect, a first statistic of a first data set of the received data from the first meter is correlated to the number of transformers, and the first meter is determined to have a likely connection to the first transformer by maximizing a correlation between the first statistic of the first data set and a second statistic of a second data set of a second meter known to be connected to the first transformer.

In another aspect, the correlation is a Pearson correlation.

In another aspect, the first data set includes a voltage magnitude.

In another aspect, the first data set include a phase data.

In another aspect, updating the initial map includes revising the connection between the first meter and the first transformer.

In another embodiment, a process for verifying and revising a mapping of a utility distribution system. The process includes receiving an initial map of a number of electrical meters and a number of transformers, wherein the initial map shows connections between the number of electrical meters and the number of transformers and receiving data from the number of electrical meters. The process further includes executing an initial adjustment to the initial map by assigning each electrical meter of the number of electrical meters to a closest transformer of the number of transformers based on a distance between each electrical meter and the closest transformer, randomly analyzing a first meter of the number of electrical meters to determine a first likely connection to a first transformer of the number of transformers, and updating a connection of the first electrical meter to the first transformer in the initial map based on the determined first likely connection.

In one aspect, the process includes executing one or more similarity measures to determine the first likely connection.

In another aspect, the process includes iteratively randomly analyzing an n+1 electrical meter of the number of electrical meters to determine an n+1 likely connection to an n+1 transformer of the number of transformers, and updating a connection of the n+1 electrical meter to the n+1 transformer in the initial map based on the determined n+1 likely connection.

In another aspect, the process finalizes the iterative random analysis in response to all n+1 meter being iteratively analyzed.

In another aspect, a first statistic of a first data set of the received data from the first meter is correlated to the number of transformers, and the first meter is determined to have a likely connection to the first transformer by maximizing a correlation between the first statistic of the first data set and a second statistic of a second data set of a second meter known to be connected to the first transformer.

In another aspect, the correlation is a Pearson correlation.

In another aspect, the first data set includes one or more of a voltage magnitude data set and a phase-data data set.

In another aspect, updating the initial map includes revising the connection between the first electrical meter and the first transformer.

In one embodiment, a utility distribution system includes a number of electrical meters, a number of transformers, and a central utility controller. The central utility controller is configured to generate an initial map of the number of electrical meters to their respective transformers, generate an initial map of the number of electrical meters to their respective transformers, and receive data from the number of electrical meters. The central utility controller is also configured to revise the initial map by assigning each meter of the number of electrical meters to a closest transformer of the number of transformers by a distance, determine a maximum number of meter per a first transformer of the number of transformers, revise the initial map to verify that the first transformer of the number of transformers does not exceed the maximum number of meters connected thereto, analyze a first electrical meter of the number of meters to determine a first likely connection to the first transformer of the number of transformers, and update a connection of the first meter to the first transformer in the initial map based on the determined first likely connection.

In another embodiment, the maximum number of electrical meters per the first transformer of the number of transformers is determined based on determining whether a power consumption of a set of electrical meters of the number of meters indicated as connected to the first transformer of the number of transformers exceeds a nominal power of the first transformer.

In another aspect, the central utility controller is further configured to iteratively randomly analyze an n+1 electrical meter of the number of electrical meters to determine an n+1 likely connection to an n+1 transformer of the number of transformers, and update the connection of the n+1 electrical meter to the n+1 transformer in the initial map based on the determined n+1 likely connection.

Other aspects of the technology will become apparent by consideration of the detailed description and accompanying drawings.

### BRIEF DESCRIPTION OF THE DRAWINGS

FIG. 1 is a system diagram illustrating a mapped electrical utility distribution system, according to some embodiments.

FIG. 2 is a block diagram illustrating a connected utility meter, according to some embodiments.

FIG. 3 is block diagram of a central utility processing system, according to some embodiments.

FIG. 4 is a flow chart illustrating a process for determining a transformer associated with a given meter, according to some embodiments.

FIG. 5 is a flow chart illustrating a sub-process for executing the process of FIG. 4, according to some embodiments.

FIG. 6 is a system diagram illustrating a remapping of the electrical utility distribution system of FIG. 1.

FIG. 7 is a system diagram illustrating a further remapping of the electrical utility distribution system of FIG. 1.

FIG. 8 is a system diagram illustrating a further remapping of the electrical utility distribution system of FIG. 1.

### DETAILED DESCRIPTION

Before any embodiments of the application are explained in detail, it is to be understood that the application is not limited in its application to the details of construction and the arrangement of components set forth in the following description or illustrated in the following drawings. The application is capable of other embodiments and of being practiced or of being carried out in various ways.

Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. As used within this document, the word “or” may mean inclusive or. As a non-limiting example, if examples in this document state that “item Z may comprise element A or B,” this may be interpreted to disclose an item Z comprising only element A, an item Z comprising only element B, as well as an item Z comprising elements A and B.

As used herein, “meter” may refer to a connected utility meter, an end point, an end device, an advanced metering infrastructure (“AMI”) meter from Aclara Technologies®, a meter communication add-on, or other metering device as required for a given application.

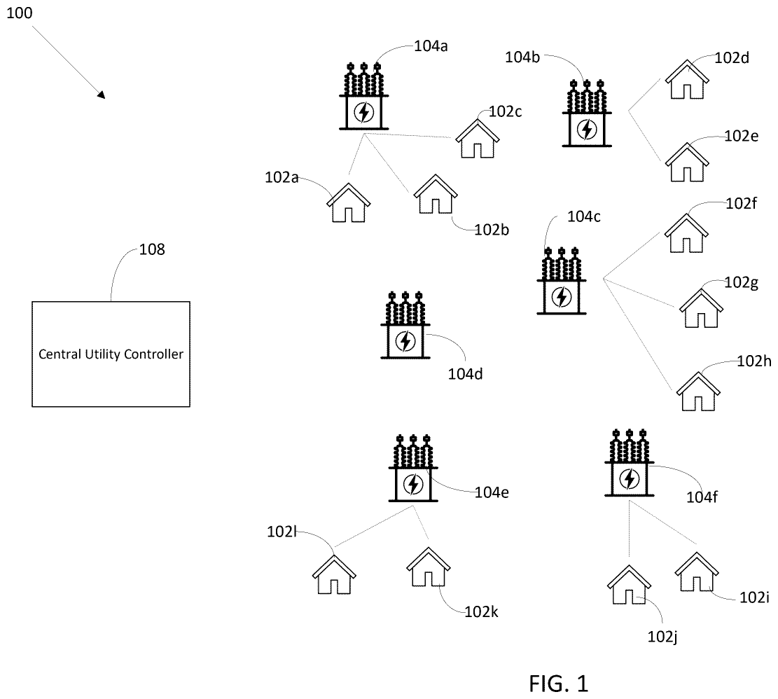

FIG. 1 illustrates a mapped electrical utility distribution system 100. The system 100 includes multiple meters 102a-l. The meters 102a-l may be general electric utility meters, smart meters, or other meter types as required for a given application. The meters 102a-l may be residential meters, commercial meters, industrial meters, municipality meters, and/or other meters as required for a given application. The meters 102a-l are associated with one or more transformers 104a-f. The transformers 104a-f may be pad mounted transformers, pole mounted transformers, underground transformers, substations transformers, and/or other transformers as required for a given application. The transformers 104a-f are generally configured to step-down a utility power voltage level to a level that is suitable for distribution.

As shown in FIG. 1, most of the transformers 104a-f have at least one meter 102a-l associated therewith. However, at least one transformer, transformer 104d, is shown as not being associated with any meters 102a-l. This may be due to improper mapping of transformers 104e-f. Mapping of transformers to meters is generally performed during installation of meters within the system 100. For example, when a new home is built, the service personnel may note that the newly installed meter of the new home is associated with a first transformer, when in fact it may be associated with a different meter within the system 100.

The mapping of system 100 illustrates that transformer 104a is associated with meters 102a-c, transformer 104b is associated with meters 102d-e, transformer 104c is associated with meters 102f-h, transformer 104f is associated with meters 102I-J, transformer 104e is associated with meters 102l-k, and transformer 104d is mapped as not being associated with any meters 102a-l. As noted above, this mapping may be based on notes and/or other information provided by utility personnel during installation of the system 100 and may not be 100% accurate. As will be described in more detail below, one or more processes and/or systems may be used to verify and/or correct the mapping shown in FIG. 1.

The system may further include a central utility controller 108. The central utility controller 108 may be in communication with the meters 102a-l, as well as one or more transformers 104a-f and/or other components within the system 100. The central utility controller 108, as will be described in more detail below, may be configured to maintain and update a mapping of the utility system 100.

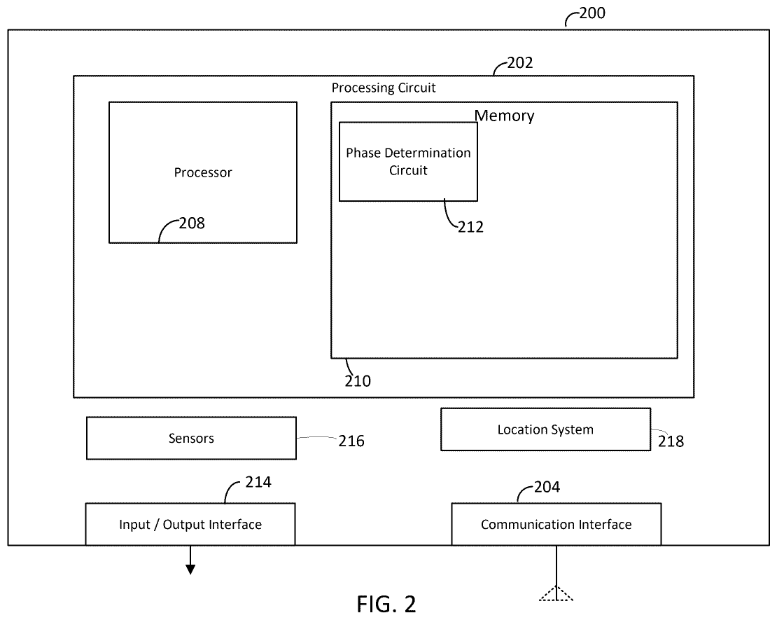

Turning now to FIG. 2 a block diagram of a meter 200 is shown, according to some embodiments. The meter 200 may be similar to meters 102a-l described above, and it is understood that the meters described herein may be interchangeable. As shown in FIG. 2, the meter 200 includes a processing circuit 202, a communication interface 204, an input/output (I/O) interface 214, and one or more sensors 216. The processing circuit 202 includes an electronic processor 208 and a memory 210. The processing circuit 202 may be communicably connected to one or more of the communication interface 204 and the I/O interface 214. The electronic processor 208 may be implemented as a programmable microprocessor, an application specific integrated circuit (ASIC), one or more field programmable gate arrays (FPGA), a group of processing components, or with other suitable electronic processing components.

The memory 210 (for example, a non-transitory, computer-readable medium) includes one or more devices (for example, RAM, ROM, flash memory, hard disk storage, etc.) for storing data and/or computer code for completing or facilitating the various processes, layers, and modules described herein. The memory 210 may include database components, object code components, script components, or other types of code and information for supporting the various activities and information structure described in the present application. According to one example, the memory 210 is communicably connected to the electronic processor 208 via the processing circuit 202 and may include computer code for executing (for example, by the processing circuit 202 and/or the electronic processor 208) one or more processes described herein.

The communication interface 204 is configured to facilitate communication between the meter 200 and one or more external devices or systems, the central utility controller 108, and/or one or more other meters. The communication interface 204 may be, or include, wireless communication interfaces (for example, antennas, transmitters, receivers, transceivers, etc.) for conducting data communications between the meter 200 and one or more external devices, such as another meter or the central utility controller 108. In some embodiments, the communication interface 204 utilizes a proprietary protocol for communicating with other meters 200 or the central utility controller 108. For example, the proprietary protocol may be an RF-based protocol configured to provide efficient and effective communication between the meters 200 and other devices. In other embodiments, other wireless communication protocols may also be used, such as cellular (3G, 4G, 5G, LTE, CDMA, etc.), Wi-Fi, LoRa, LoRaWAN, Z-wave, Thread, and/or any other applicable wireless communication protocol.

The I/O interface 214 may be configured to interface directly with one or more devices, such as a power supply, a power monitor, etc. In one embodiment, the I/O interface 214 may utilize general purpose I/O (GPIO) ports, analog inputs, digital inputs, etc. The sensors 216 may include one or more sensors configured to monitor one or more aspects of a distribution line coupled to the meter 200. For example, the sensors 216 may include voltage sensors, current sensors, temperature sensors, and other sensors as required for a given application. In some embodiments, the sensors 216 include one or more connections between the node 106 and the connected distribution line. In other examples, the sensors 216 may be connected to the distribution line using the I/O interface 214.

The meter 200 may further include a location system 218. The location system 218 may provide location data of the meter 200. In some examples, the location system 218 may utilize geolocation satellite data (e.g., GPS, GLONASS, etc.) to determine a location of the meter 200. However, other location determination technologies (e.g., cellular triangulation, Wi-Fi location, or other location service required for a given application) may also be used by the location system 218.

As described above, the memory 210 may be configured to store various processes, layers, and modules, which may be executed by the electronic processor 208 and/or the processing circuit 202. In one embodiment, the memory 210 includes a phase determination circuit 212. The phase determination circuit 212 is configured to determine, in concert with the electronic processor 208 and the sensors 216, phase information of the electrical utility monitored by the meter 200. In one embodiment, the phase information is transmitted to the central utility controller 108 via the communication interface 204.

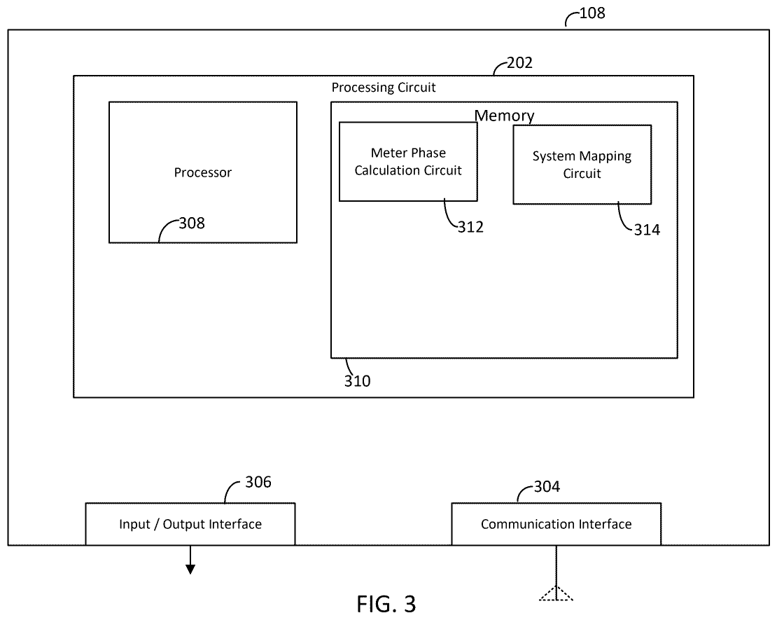

Turning now to FIG. 3 a block diagram of the central utility controller 108 is shown, according to some embodiments. As shown in FIG. 3, the central utility controller 108 includes a processing circuit 302, a communication interface 304, and an input/output (I/O) interface 306. The processing circuit 302 includes an electronic processor 308 and a memory 310. The processing circuit 302 may be communicably connected to one or more of the communication interface 304 and the I/O interface 306. The electronic processor 308 may be implemented as a programmable microprocessor, an application specific integrated circuit (ASIC), one or more field programmable gate arrays (FPGA), a group of processing components, or with other suitable electronic processing components.

The memory 310 (for example, a non-transitory, computer-readable medium) includes one or more devices (for example, RAM, ROM, flash memory, hard disk storage, etc.) for storing data and/or computer code for completing or facilitating the various processes, layers, and modules described herein. The memory 310 may include database components, object code components, script components, or other types of code and information for supporting the various activities and information structure described in the present application. According to one example, the memory 310 is communicably connected to the electronic processor 308 via the processing circuit 302 and may include computer code for executing (for example, by the processing circuit 302 and/or the electronic processor 308) one or more processes described herein.

The communication interface 304 is configured to facilitate communication between the central utility controller 108 and one or more external devices or systems, such as one or more other meters 102a-l. The communication interface 304 may be, or include, wireless communication interfaces (for example, antennas, transmitters, receivers, transceivers, etc.) for conducting data communications between the central utility controller 108 and one or more external devices, such as another meter 102a-l. In some embodiments, the communication interface 304 utilizes a proprietary protocol for communicating. For example, the proprietary protocol may be an RF-based protocol configured to provide efficient and effective communication between the central utility controller 108 and other devices. In other embodiments, other wireless communication protocols may also be used, such as cellular (3G, 4G, 5G, LTE, CDMA, etc.), Wi-Fi, LoRa, LoRaWAN, Z-wave, Thread, and/or any other applicable wireless communication protocol.

The I/O interface 306 may be configured to interface directly with one or more devices, such as a power supply, a power monitor, etc. In one embodiment, the I/O interface 214 may utilize general purpose I/O (GPIO) ports, analog inputs, digital inputs, etc.

As described above, the memory 310 may be configured to store various processes, layers, and modules, which may be executed by the electronic processor 308 and/or the processing circuit 302. In one embodiment, the memory 310 includes a meter phase calculation circuit 312. The meter phase calculation circuit 312 is configured to determine, in concert with the electronic processor 308, a phase of each of the meters 102a-l within the system 100. In one embodiment, the meter phase calculation circuit 312 determines the phase based at least on phase information and/or other data provided by the meters 102a-l.

The memory 310 may further include a system mapping circuit 314. The system mapping circuit 314 may be configured to map the one or more meters 102a-l of the system 100 to their respective transformers 104a-f, as will be described in more detail below.

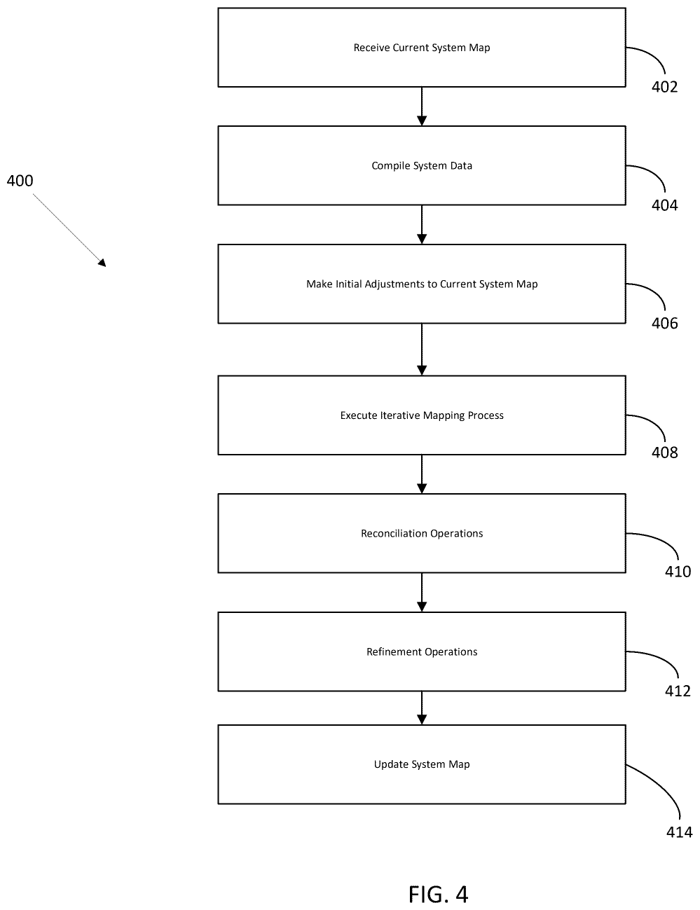

Turning now to FIG. 4, a flow chart illustrating a process 400 for updating a mapping of meters, such as meters 102a-l, within a utility distribution system, such as utility distribution system 100, is described, according to some embodiments. In one embodiment, the process 400 is performed by the system mapping circuit 314 of the central utility controller 108 described above. However, in other embodiments, one or more other components or devices may execute the process 400. For the sake of brevity, the process 400 will generally be described as being performed by the central utility controller 108.

At process block 402, a current system map of the system 100 is provided to the central utility controller 108. In some examples, the current system map of the system 100 is manually entered into the central utility controller 108. In other examples, the current system map is generated based on previously provided data. In another embodiment, the current system map of the system 100 is generated by the central utility controller 108 by assigning each meter 102a-l within the system 100 to its closest transformer 104a-f based on a distance between the meters 102a-l and the transformers 104a-f. In one example, the distance is a Euclidian distance between respective coordinates (e.g., longitude and latitude) of the meters 102a-l and the transformers 104a-f. In some examples, the central utility controller 108 may generate a projection of the coordinates on a two-dimensional plane.

At process block 404, the central utility controller 108 compiles data associated with the system 100. Data may include the adjusted connections made during process block 406, described below Other data may include time series data from the meters 102a-l. The time series data may include voltage phase data, phasor data, voltage levels, current, location data (e.g., GPS data, Wi-Fi location data, or other location data as required for a given application), and/or other data as required for a given application.

At process block 406, initial adjustments are made to the current system map of the system 100. For example, one or more constraints may be required to be met before adjustments are made to the current system map. In one embodiment, six constraints are required to be satisfied: (1) every meter 102a-l must be connected to one and only one transformer 104a-f; (2) the meters 102a-l must be in phase agreement with the associated transformer 104a-f (i.e., only one phase per transformer); (3) meters 102a-l are moved away from transformer 104a-f that does not share the same phase; (4) every meter 102a-l must be assigned to a single transformer 104a-f; (5) each transformer 104a-f must have at least one meter 102a-l connected to it (unless it is located near non-metered service areas such as street lighting, billboards, etc.); and (6) the number of meters 102a-l connected to the same transformer 104a-f must be limited, either by a given quantity or based on an aggregated power consumption of the meters coupled to the transformer.

With respect to the first constraint, each meter is generally assigned to only one transformer, thereby satisfying this constraint. In one example, in the event a meter 102a-l is mapped to more than one transformer 104a-f, the meter may be assigned to the transformer that is closest in distance to the meter. However, other actions to satisfy the above constraint are also contemplated as required for a given application. With respect to the second constraint, in the event there is a transformer 104a-f without any connected meters 102a-l, the central utility controller 108 may perform one or more actions to satisfy the second constraint. For example, the central unitality controller may select one or more meters to be connected to the transformer, remove the transformer from the list of transformers 104a-f, and/or perform other actions as required for a given application. In one embodiment, the central utility controller 108 will select the meter 102a-l that is located closest to the transformer 104a-f to assign to the transformer that has no associated meter. This ensures that the closest meter 102a-l to the transformer 104a-f is not the only one connected to prevent leaving any transformers without any associated meters. Having a transformer 104a-f with no associated meters 102a-l can results in the process 400 potentially being stuck in an infinite loop.

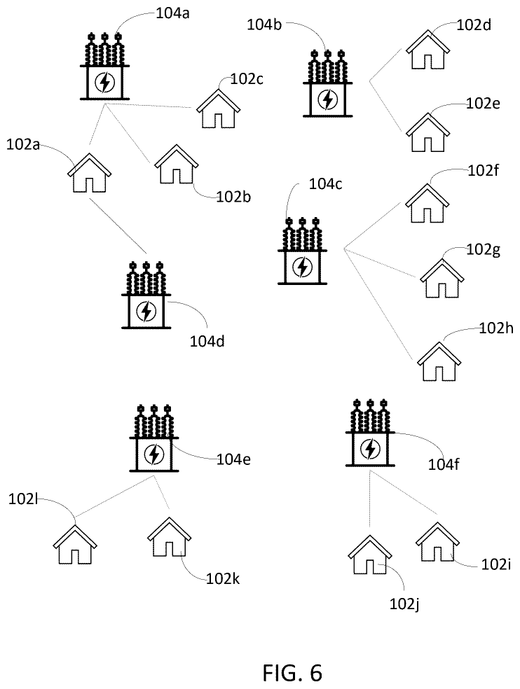

This is illustrated in FIG. 6, which shows the map of system 100 as being revised in response to the initial adjustments, such that transformer 104d has at least one meter 102a connected thereto.

With respect to the sixth constraint, the maximum number of meters 102a-l are determined per transformer 104a-f. In one embodiment, the central utility controller 108 may use a predefined maximum number of meters 102a-l per transformer 104a-f. For example, the utility and/or distribution company associated with the utility system 100 may set the maximum allowable number of meters 102a-l for a transformer 104a-f. This maximum allowable number of meters 102a-l may be based on various factors, such as transformer capacity, network load balancing, operational constrains, and/or other factors as required for a given application.

In other embodiments, the maximum number of meters 102a-l per transformer 104a-f may be dynamically determined. In one example, the maximum number is based on the nominal power of the transformer 104a-f and the aggregated consumption of connected meters 102a-l. The idea is to define a factor (α) for determining the maximum allowable overload of a transformer 104a-f as α times the nominal power of the transformer 104a-f. Upon the factor α being determined, a time window may be established during which the aggregated meters 102a-l consumption is allowed to exceed the maximum allowable overload value. Accordingly, in response to the maximum allowable overload value is exceeded during the defined window, the central utility controller 108 determines that the allowable limit of meters 102a-l for a given transformer 104a-f has been exceeded.

In the event that the allowable number of meters 102a-l for a given transformer 104a-f has been exceeded, the central utility controller 108 is configured to modify the mapping of the system 100 to reassign meters 102a-l to ensure that no transformers 104a-f exceed the maximum allowable number of meters. First, the central utility system determines three distance thresholds (γ₁, γ₂) and (β). The distance thresholds γ₁, γ₂ establish a maximum distance limits between a meter 102a-l and a transformer 104a-f in the system 100, and the distance threshold β establishes a minimum distance limit between a meter 102a-l and a transformer 104a-f in the system 100. Thus, any meter 102a-l that exceeds the γ₁, γ₂ distance threshold is considered an impossible connection. Conversely, any meter 102a-l located within a distance less than distance β from a given transformer 104a-f will be regarded by the central utility controller 108 as a correct and unchangeable connection. Transformers 104a-f may be categorized in three ways, in one embodiment. For example, a transformer 104a-f having only one meter 102a-l connected thereto may be referred to as a singly-connected transformer; a transformer 104a-f having multiple meters 102a-l attached thereto may be referred to as a multiply-connected transformer, and a transformer 104a-f having no meters 102a-l attached thereto may be referred to as a widow-transformer.

The central utility controller 108 may then define a neighborhood of the k closest transformers 104a-f to a given meter 102a-l. Specifically, the k neighborhood represents a set of transformers 104a-f that are within a certain distance constraint, such as γ₁, γ₂ distance threshold, described above. Thus, the central utility controller 108 may exclude any transformers 104a-f in the defined neighborhood that exceeds the γ₁, γ₂ distance threshold is excluded from the neighborhood, resulting in a neighborhood size that can be equal to or less than k.

A restricted neighborhood may further be defined based on a voltage angle value between transformers 104a-f. The central utility controller 108 may select only those transformers 104a-f within the defined neighborhood that have a target meter mᵢ that has a voltage angle value that is within an acceptable deviation between the target meter mᵢ and the meters 102a-l connected to the transformer. In one embodiment, the central utility controller 108 may determine a median value of phase angle within a time series of data and compare that to a median value of phase angle for the other applicable meters; however, it is understood that the central utility controller 108 may utilize other processes to select the transformers 104a-f within the defined neighborhood that have a target meter mᵢ that has a voltage angle value that is within an acceptable deviation between the target meter mᵢ and the meters 102a-l connected to the transformer as required for a given application. This process may be repeated for each of the meters 102a-f within the neighborhood and/or meters indicated as connected to the specific transformer.

Thus, the process for each transformer 104a-f exceeding the maximum number of connected meters involves iteratively removing meters based on certain criteria. As noted above, the meters with the lowest correlation in a voltage phase time series data compared to the other meters 102a-l median voltage phase time series data are selected for removal from a given transformer 104a-f. This prioritizes meters 102a-l that contribute less to the overall coherence within the transformer. The removed meters 102a-l may then be reassigned to a transformer 104a-f within their restricted neighborhood that maximizes the correlation between their voltage time series and the median voltage phase time series data and the median voltage phase time series data of the meters 102a-l associated with the transformer 104a-f. This maintains the overall coherence and minimizes the disruption caused by meter reassignments.

This reassignment process may continue until the transformer 104a-f no longer exceeds the maximum number of connected meters ensuring that the connectivity constraints and the specified correlation requirements are satisfied.

At process block 408, the central utility controller 108 executes an iterative mapping process to update and/or verify the mapping of system 100 having n electrical meters and m transformers, where n represents any whole number and m is less than or equal to n.

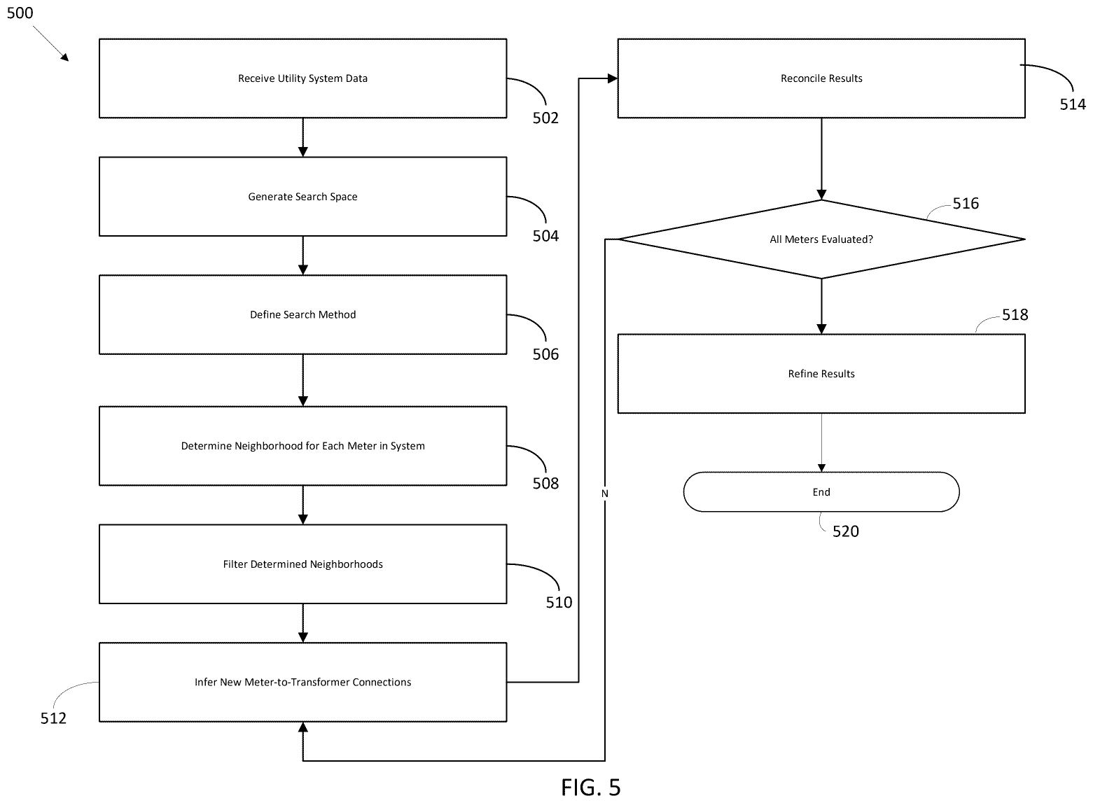

Turning now to FIG. 5, an iterative mapping process 500 is shown in more detail. In one embodiment, the central utility controller 108 is configured to perform the process 500, such as via the system mapping circuit 314. However, it is contemplated that various other systems, controllers, processors, or the like may be used to perform the process 500, as required for a given application.

At process block 502, the central utility controller 108 receives data associated with the system 100. The data may be received from the meters 102a-l within the system. In one embodiment, the data includes the data compiled at process block 406 in process 400, as described above.

At process block 504, the central utility controller 108 generates a search space that identifies a collection of meters 102a-l to be analyzed by the process 500 for potential changes in the meter-to-transformer connectivity. In one embodiment, the search space is generated based on specified criteria. The specified criteria may be distance based; however other criteria are contemplated for a required application. In one example, the search space may include all meters 102a-l that are not the sole connection to their assigned transformer and are located at a distance greater than β from their respective transformers 104a-f. Meters 102a-l having a distance less than β from their respective transformers 104a-f may be considered to be unchangeable, in some examples. Other criteria used to generate a search space may include minimum and/or maximum distance to a corresponding transformer 104a-f from a meter 102a-l; meters 102a-l not alone in their transformer 104a-f; data availability (e.g., not more than a specific percentage of NaN's or at least one voltage angle value available); meters 102a-l within a specific area; single phase meters 102a-l; etc.

Upon generating the search space, the central utility controller 108 defines a search method at process block 506. The search method determines how the previously defined search space is traversed. In one example, the central utility controller 108 may default to analyzing meters 102a-l within the search space randomly. As the process 500 is iterative in nature, this can result in slightly different solutions being generated for each run. In other examples, non-random alternatives are recommended to promote consistency, such as traversing the search space from the meter 102a-l farthest from its assigned transformer to the meter closest to its transformer 104a-f. In still other examples the search space may be sorted based on the distance between the meters 102a-l and their corresponding transformers 104a-f, and then traversed in descending order.

At process block 508, the central utility controller 108 determines a neighborhood for each meter 102a-l. The neighborhood is determined to include the k-closest transformers 104a-f with respect to distance, such as Euclidian distance or Haversine distance. As noted above, the distance may be a preassigned constraint. Furthermore, the number k may be a predefined value assigned by the central utility controller 108. For example, the central utility controller 108 may define the distance of the neighborhood, such as the γ₁, γ₂ distance threshold described above. Further, as the transformers 104a-f must also satisfy the maximum distance constraint, i.e., not be at a distance further than the γ₁, γ₂ distance threshold, in some instances the size of the transformer neighborhood may be smaller than k. As noted above, the meters 102a-l may provide location data the central utility controller 108.

At process block 510, the determined neighborhood is then filtered by the central utility controller 108. Once the neighborhood of the target meter mᵢ has been determined and adjusted, only those transformers 104a-f containing meters that ensure neighborhood coherence with respect to the phase of the of the target meter mᵢ should be filtered out. For example, transformers 104a-f of a different phase than the meters 102a-l will be filtered out as only transformers coupled to the same phase as the meter can be assigned together. In some embodiments, the phase of a respective meter 102a-l is determined by the central utility controller 108, such as via the meter phase calculation circuit 312. However, in other examples, a meter 102a-l may determine its own phase, such as via the phase determination circuit 212.

At process block 512, the central utility controller 108 infers new meter 102a-l to transformer 104a-f connections within the defined search space. In one embodiment, the central utility controller 108 selects a transformer 104a-f that maximizes a similarity measure between a specific statistic within the time series data provided by the meters 102a-l. Multiple similarity measures may be used to determine the transformer 104a-f a target meter mᵢ is connected to. Each of the herein described similarity measures compare the similarity of one or more transformers 104a-f candidates that may be connected to a target meter mᵢ, specifically within a phase restricted neighborhood, or other neighborhood, as described above.

In one embodiment, the similarity measure is a Pearson correlation. However, other similarity measures may also be used. Statistics may include various values of the time series data, such as mean, median, mode and/or range. In some examples, magnitudes of certain sensed parameters, such as voltage, current, etc., may be analyzed. Based on the analysis, a transformer 104a-f within the phase restricted neighborhood may be selected to be connected to the target meter mᵢ that maximizes the correlation of the desired magnitude (V) between the meter and the meter in the transformer. This may be expressed using Equation 1, below.

$${m}_{i} \to {t}_{υ} , where {t}_{υ} = {max}_{{t}_{j} ∈ {N}_{k}^{θ} ( {m}_{i} )} \{ coor ( V ( {m}_{i} ) , \overline{V} ( MS ( {t}_{j} ) ) ) \} \qquad EQUATION 1$$

In one embodiment, the similarity measure is a maximum voltage time-based normalization correlation. For example, each transformer 104a-f within the phase restricted neighborhood, a median of the Pearson correlation between a maximum voltage (V max, normalized on time) of each meter of the transformer (without the target meter mᵢ) and the voltage of the target meter mᵢ is used to generate a score using Equation 2, below.

$${score}_{1} ( {m}_{i} , {t}_{j} ) = {median}_{m ∈ MS ( {t}_{j} ) \backslash \{ {m}_{i} \}} ( corr ( {V}_{max} ( m ) , {V}_{max} ( {m}_{i} ) ) ) , \qquad EQUATION 2$$

$$∀ {t}_{j} ∈ {N}_{k}^{θ} ( {m}_{i} )$$

The transformer with the maximum score is then selected. In the case that there is no maximum voltage data of the target meter mᵢ or any of the meters connected to the transformers in the phase restricted neighborhood, there will not be a selected transformer and the scores will be undefined. In the case that there is only one transformer 104a-f within the phase restricted neighborhood, there will not be a selected transformer.

In another embodiment, the similarity measure is a delta power-based two-fold average voltage correlation. This correlation differs from other herein described correlations as the delta power-based two-fold average voltage correlation does not obtain a single score independent from the rest of the transformers 104a-f within the phase restricted neighborhood. Instead, the first two transformers 104a-f within the phase restricted neighborhood are selected and a mean of the active power (P) of the meters 102a-l (without the target meter mᵢ) is calculated using Equation 3, below.

$$\overline{P} ( MS ( {t}_{r} ) \backslash \{ {m}_{i} \} ) = {mean}_{m ∈ ( MS ( {t}_{r} ) \backslash \{ {m}_{i} \}} ( P ( m ) ) , \qquad EQUATION 3$$

$$P ( MS ( {t}_{s} ) \backslash \{ {m}_{i} \} ) = {mean}_{m ∈ ( MS ( {t}_{a} ) \backslash \{ {m}_{i} \}} ( P ( m ) ) .$$

A difference between consecutive time stamps of the results is then calculated, as shown below in Equation 4.

$$Δ \overline{P} ( MS ( {t}_{r} ) \backslash \{ {m}_{i} \} ) , \qquad EQUATION 4$$

$$Δ \overline{P} ( MS ( {t}_{r} ) \backslash \{ {m}_{i} \} ) .$$

Valid intervals (VI) are then selected based on when the difference of the transformers' 104a-f power jump exceeds a threshold. For example, the VI may be calculated using Equation 5, shown below.

$$VI ( {t}_{r} , {t}_{s} ) = \text{} \text{} \{ l ∈ \{ 1 , … , z - 1 \} : \vert Δ {\overline{P} ( MS ( {t}_{r} ) \backslash \{ {m}_{i} \} )}_{l} - Δ {\overline{P} ( MS ( {t}_{s} ) \backslash \{ {m}_{i} \} )}_{l} \vert > {tol}_{1} \} . \qquad EQUATION 5$$

Then, the time intervals of VI(tᵣ, tₛ) are eliminated where the time series of any of the power jumps has NaN values. Where the number of time intervals remaining is lower than a tolerance, tol₂, the delta power-based two-fold average voltage correlation is started again with the next two transformers 104a-f within the phase restricted neighborhood. The difference between consecutive time stamps of the average voltage (V_{avg}) of all meters 102a-l connected to each transformer 104a-f within the phase restricted neighborhood (without the target meter mᵢ) and the target meter mᵢ, and the valid intervals are then filters based on one or more time series. For example, the time series may be defined as shown in Equation 6, below.

$$Δ {V}_{avg} ( MS ( {t}_{r} ) \backslash \{ {m}_{i} \} ) {\vert}_{VI ( {t}_{r} , {t}_{s} )} , \qquad EQUATION 6$$

$$Δ {V}_{avg} ( MS ( {t}_{s} ) \backslash \{ {m}_{i} \} ) {\vert}_{VI ( {t}_{r} , {t}_{s} )} ,$$

$$Δ {V}_{avg} ( {m}_{i} ) {\vert}_{VI ( {t}_{r} , {t}_{s} )} .$$

Any time intervals where the time series has NaN values are then eliminated. The delta power-based two-fold average voltage correlation is then started again with the next two processors where number of time intervals remaining is lower than the previous tolerance, tol₂. Finally, the mean of a Pearson correlation of the filtered time series of the meters 102a-l of each transformer 104a-f is compared to the filtered time series of the target meter mᵢ. For example, the mean of a Pearson correlation of the filtered time series of the meters 102a-l of each transformer 104a-f may be compared to the filtered time series of the target meter mᵢ using Equation 7, below, to determine which score is greater.

$${score}_{2} ( {m}_{i} , {t}_{r} {\vert}_{{t}_{s}} ) = {mean}_{m ∈ MS ( {t}_{r} ) \backslash \{ {m}_{i} \}} ( corr ( Δ {V}_{avg} ( m ) {\vert}_{VI ( {t}_{r} , {t}_{s} )} , Δ {V}_{avg} ( {m}_{i} ) {\vert}_{VI ( {t}_{r} , {t}_{s} )} ) ) , \qquad EQUATION 7$$

$${score}_{2} ( {m}_{i} , {t}_{s} {\vert}_{{t}_{r}} ) = {mean}_{m ∈ MS ( {t}_{s} ) \backslash \{ {m}_{i} \}} ( corr ( Δ {V}_{avg} ( m ) {\vert}_{VI ( {t}_{r} , {t}_{s} )} , Δ {V}_{avg} ( {m}_{i} ) {\vert}_{VI ( {t}_{r} , {t}_{s} )} ) ) ,$$

Based on the scores, various transformers from the phase restricted neighborhood may be eliminated. For example, where score₂(mᵢ, tᵣ\tₛ)>score₂(mᵢ, tₛ\tᵣ), transformer tₛ is eliminated from the phase restricted neighborhood and the delta power-based two-fold average voltage correlation is then started again with transformer tᵣ. Where score₂(mᵢ, tₛ\tᵣ)>score₂(mᵢ, tᵣ\tₛ), transformer tᵣ is eliminated from the phase restricted neighborhood, and the delta power-based two-fold average voltage correlation is then started again with the next transformer from the phase restricted neighborhood. Where score₂(mᵢ, tᵣtₛ)=score₂ (mᵢ, tsVr), the delta power-based two-fold average voltage correlation is started again with the transformer tₛ and the next transformer in the phase restricted neighborhood. Finally, where there is only one transformer left in the phase restricted neighborhood (tᵣ), that transformer is selected as the most likely transformer associated with the target meter mᵢ. In the case that the delta power-based two-fold average voltage correlation does not converge, no transformer will be selected. Similarly, in the case that there is only one transformer in the phase restricted neighborhood, no transformer will be selected.

In another embodiment, the similarity measure is a maximum voltage correlation. Here, for each transformer within the phase restricted neighborhood, a Pearson correlation between the median of the maximum voltage (Vₘₐₓ, not normalized) of the meters 102a-l and the transformer 104a-f (without the target meter mᵢ) and the voltage of the target meter mᵢ is determined. In one example, the Pearson correlation may be determined using Equation 8, shown below.

$$\begin{matrix}{score}_{3} ( {m}_{i} , {t}_{j} ) = corr ( {median}_{m ∈ MS ( {t}_{j} ) \backslash \{ {m}_{i} \}} ( {V}_{max} ( m ) ) , {V}_{max} ( {m}_{i} ) ) \\ = corr ( {\tilde{V}}_{max} ( MS ( {t}_{j} ) \backslash \{ {m}_{i} \} ) , {V}_{max} ( {m}_{i} ) ) ,\end{matrix} \qquad EQUATION 8$$

$$∀ {t}_{j} ∈ {N}_{k} ( {m}_{i} )$$

Here, only meters 102a-l connected to a transformer 104a-f having a full maximum voltage time series not equal to zero are considered. The transformers 104a-f with the two highest scores are then determined and a difference between the transformers having the two highest scores is calculated. Equation 9, below, illustrates this determination in more detail.

$$\{ \begin{matrix}{t}_{v} = arg {max}_{{i}_{j} ∈ {N}_{k} ( {m}_{i} )} \{ {score}_{3} ( {m}_{i} , {t}_{j} ) \} , \\ {t}_{w} = arg {max}_{{i}_{j} ∈ {N}_{k} ( {m}_{i} ) \backslash \{ {t}_{s} \}} \{ {score}_{3} ( {m}_{i} , {t}_{j} ) \} , \\ {score}_{3} ( {m}_{i} , {t}_{υ} ) > {score}_{3} ( {m}_{i} , {t}_{w} ) + tol ,\end{matrix} \qquad EQUATION 9$$

In response to the difference between the two highest scores exceeding a threshold value (tol), the transformer 104a-f with the highest score is selected. In the event that there is no maximum voltage data for the target meter mᵢ or any of the meters 102a-l connected to the transformers 104a-f in the phase restricted neighborhood, there will be no selected transformer. Also, in the event that the difference between the two highest scores not exceeding the threshold value (tol), the selected transformer 104a-f will be the one with the highest score.

In another embodiment, the similarity measure is a maximum voltage probability-density-based likelihood maximization. The maximum voltage probability-density-based likelihood maximization presumes that the voltage (V) time series of each meter can be divided into D time series of length d, which will be referred to as fragmented time series data of a meter. The fragmented time series data can be expressed as shown in Equation 10, below.

$$\{ \begin{matrix}{V}_{1} ( {m}_{i} ) = ( {υ}_{1}^{i} , … , {υ}_{d}^{i} ) , \\ {V}_{2} ( {m}_{i} ) = ( {υ}_{d + 1}^{i} , … , {υ}_{2 d}^{i} ) , \\ … \\ {V}_{D} ( {m}_{i} ) = ( {υ}_{z - d + 1}^{i} , … , {υ}_{z}^{i} ) .\end{matrix} \qquad EQUATION 10$$

For each transformer 104a-f of the phase restricted neighborhood, a probability density function is estimated, such as with a kernel density estimator, with respect to a reconstructed phase space of the maximum voltage (Vₘₐₓ, normalized on a meter 102a-l) of the meters of the transformer (without the target meter mᵢ). The reconstructed phase space may be defined using Equation 11, below.

$${RPS}_{V} ( A ) = [ {V}_{1} ( {m}_{i} ) {V}_{2} ( {m}_{i} ) … {V}_{D} ( {m}_{i} ) ] = [ \begin{matrix}{υ}_{1}^{i} & {υ}_{d + 1}^{i} & … & {υ}_{z - d + 1}^{i} \\ {υ}_{2}^{i} & {υ}_{d + 2}^{i} & … & {υ}_{z - d + 2}^{i} \\ ⋮ & ⋮ & ⋱ & ⋮ \\ {υ}_{d}^{i} & {υ}_{2 d}^{i} & … & {υ}_{z}^{i}\end{matrix} ] \qquad EQUATION 11$$

The probability density function may be implemented as shown in Equation 12, as shown below.

$$f {RPS}_{{V}_{max}} ( MS ( {t}_{j} ) \backslash \{ {m}_{i} \} ) \to {\hat{f}}_{{t}_{j}} ( {υ}_{max , 1} , … , {υ}_{max , d} ) , \qquad EQUATION 12$$

$$∀ {t}_{j} ∈ {N}_{k}^{θ} ( {m}_{i} )$$

Each function in each fragmented time series of the target meter mᵢ may be evaluated to obtain a probability for one or more cases. For example, the probabilities may be determined using Equation 14, below, using Equation 13 to estimate a probability density function used in Equation 14.

$$f {RPS}_{{V}_{max}} ( MS ( {t}_{j} ) \backslash \{ {m}_{i} \} ) \to {\hat{f}}_{{t}_{j}} ( {υ}_{max , 1} , … , {υ}_{max , d} ) , \qquad EQUATION 13$$

$$∀ {t}_{j} ∈ {N}_{k}^{θ} ( {m}_{i} )$$

A probability that each fragmented time series follows the probability distribution of the probability density function of the transformer for every case for each fragmented time series of the target meter mᵢ is then determined. For example, the probabilities may be determined using Equation 14, below.

$${p}_{l , j} = {\hat{f}}_{{t}_{j}} ( {V}_{max , l} ( {m}_{i} ) ) , l = 1 , … , D , ∀ {t}_{j} ∈ {N}_{k}^{θ} ( {m}_{i} ) \qquad EQUATION 14$$

A score is then calculated for each transformer 104a-f of the phase restricted neighborhood is then calculated based on the proportion of a corresponding probability that are a magnitude (tol₂) times greater than or equal to the corresponding probabilities of the rest of the transformers 104a-f. For example, the score may be determined using Equation 15, below.

$${score}_{4} ( {m}_{i} , {t}_{j} ) = \frac{\vert \begin{matrix}( I ∈ \{ 1 , … , D \} : {p}_{i , j} \geq {tol}_{1} \cdot \\ {p}_{l , υ} , ∀ {t}_{υ} ∈ {N}_{k}^{θ} ( {m}_{i} ) \backslash \{ {t}_{j} \} \}\end{matrix} \vert}{D} , \qquad EQUATION 15$$

$$∀ {t}_{j} ∈ {N}_{k}^{θ} ( {m}_{i} )$$

It is then determined whether the maximum score of the transformers 104a-f of the phase restricted neighborhood is greater than or equal to a threshold (tol₂), and a transformer 104a-f with the highest score is then selected as being associated with the target meter mᵢ. Where there is no maximum voltage data of the target meter mᵢ, no transformer 104a-f will be selected. In the event that there is only one transformer 104a-f in the phase restricted neighborhood, no transformer 104a-f will be selected. In the event that a maximum score is less than tol₂, the selected transformer 104a-f will be the transformer with the highest score, with no numeric score associated.

Upon applying the one or more similarity measures, the results are analyzed to obtain a corresponding selected transformer 104a-f for each of the similarity measures, along with their respective scores.

At process block 514, the results of the similarity measures may then be reconciled. For example, the results of each of the one or more applied similarity measures may be evaluated to determine the correct or most probable transformer 104a-f for a target meter mᵢ. In one embodiment, the results of the similarity measures may be reconciled using one or more processes, such as an estimated secondary average voltage R² maximization process. However, other processes and/or calculation may be used as required for a given application.

With respect to the estimated secondary average voltage R² maximization process, for each transformer of a subset of transformers (T), an average voltage (V_{avg}, not normalized) and the active (Iᵣ) and reactive (Iₓ) components of current of the target meter (mᵢ) and the meters connected to the transformer 104a-f. Time stamps for any results with no score (e.g., NaN) are eliminated. Where the number of time stamps remaining is lower than a tolerance value (tol), any associated transformers 104a-f are discarded. Additionally, in some examples, only meters 102a-l connected with full average voltage time series not equal to zero are considered. Where the number of remaining meters (without the target meter mᵢ) is equal to zero, the associated transformer 104a-f is discarded as a candidate.

For every meter 102a-l connected to a candidate transformer (except for the target meter mᵢ), a liner regression between a meter 104a-l and a target meter mᵢ is used to estimate an impedance (R, X) of each of one or more service lines. For example, the linear regression may be performed using an equation, such as Equation 16 illustrated below.

$${V}_{avg} ( {m}_{i} ) = {β}_{0} + {β}_{1} {V}_{avg} ( m ) + R ( m ) {I}_{r} ( m ) + X ( m ) {I}_{z} ( m ) - R ( {m}_{i} ) {I}_{r} ( {m}_{i} ) - X ( {m}_{i} ) {I}_{x} ( {m}_{i} ) , \qquad EQUATION 16$$

$$∀ m ∈ MS ( {t}_{j} ) \backslash \{ {m}_{i} \} , ∀ {t}_{j} ∈ T .$$

An R² value for each regression may then be determined. For example, the R² value may be determine using an equation such as Equation 17, below.

$${R}_{{m}_{i} , m}^{2} , ∀ m ∈ MS ( {t}_{j} ) \backslash \{ {m}_{i} \} , ∀ {t}_{j} ∈ \ddot{T} , \qquad EQUATION 17$$

Then, for each transformer within the phase restricted neighborhood, a mean of the R² between meters 102a-l connected to the respective transformer (without the target meter mᵢ) and the target meter mᵢ is determined. In one embodiment, the mean is determined using Equation 17, below.

$${score}_{3} ( {m}_{i} , {t}_{2} ) = {mean}_{m ∈ MS ( {t}_{j} ) \backslash \{ {m}_{i} \}} ( {R}_{{m}_{i} , m}^{2} ) , ∀ {t}_{j} ∈ \ddot{T} \qquad EQUATION 18$$

A transformer 104a-f within the phase restricted neighborhood with the highest score may then be selected. In one example, a transformer 104a-f within the phase restricted neighborhood may be selected for each of the above noted similarity measures having the highest score. However, in some examples, a transformer 104a-f may only be selected for some of the similarity measures. In the case that the full average voltage time series of the target meter mᵢ is equal to zero and/or all the transformers 104a-f have been discarded because of a low number of valid time stamps/no meters connected (without target meter mᵢ) with no full average voltage time series equal to zero, no transformer may be selected.

At process block 514, the results of the similarity measures are reconciled, as will be described in more detail below For each target meter mᵢ, this may involve comparing the results of the applied similarity measures and the transformer 104a-f that was initially believed to be coupled to the target meter mᵢ. For example, there are four possible cases that may occur, as described in more detail below.

In the first case, all of the applied similarity measures select the original transformer 104a-f believed to be connected to the target meter mᵢ. In other words, each of the similarity measures agree that the original transformer associated with the target meter mᵢ is correct. The selected transformer 104a-f, which is the original transformer associated with the target meter mᵢ is then stored as the transformer coupled to the target meter mᵢ and the corresponding scores from each of the similarity measures is saved as well for future reference and refinement of subsequent analysis within a system, such as within the central utility controller 108.

In a second case, all of the applied similarity measures select the same transformer 104a-f within the phase restricted neighborhood, but it is different from the current transformer 104a-f mapped to the target meter mᵢ. Thus, all similarity measures agree on the transformer 104a-f and a score is generated for the connection with respect to the second case, such as within the central utility controller 108.

In a third case, the applied similarity measures did not all select the same transformer 104a-f, and all of the selected transformers 104a-f are different from the current transformer 104a-f associated with the target meter mᵢ. Here, the system, such as via the central utility controller 108, understands that the output of the similarity measures is incorrect and generates an alert indicating that the current connection is incorrect. In some examples, the central utility controller 108 keeps the current transformer 104a-f associated with the target meter my until a correct connection is determined. In some instances, the estimated secondary average voltage R² maximization process may be applied to the subset of transformers 104a-f generated by the similarity measures, and a score is generated and saved for the subset of transformers 104a-f.

In a fourth case, the similarity measures do not all select the same transformer 104a-f, and at least one of the similarity measures select the current transformer 104a-f associated with the target meter mᵢ.

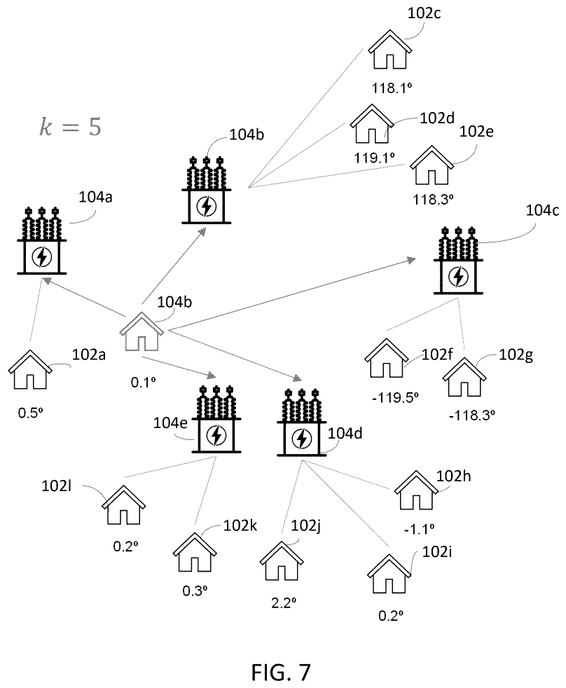

As noted above, the selected transformer 104a-f may either be the same as the one already assigned to the target meter mᵢ or a new transformer 104a-f. In response to the selected transformer 104a-f being a new transformer, the new relationship is stored for later evaluation. An example representation of the proposed new relationships can be seen in FIG. 7.

At process block 516, the central utility controller 108 determines whether all meters 102a-l have been evaluated. In response to determining that meters 102a-l have not all been evaluated, the process 500 returns to process block 512. In response to determining that all meters 102a-l have been evaluated, the process 500 may, at process block 518, perform one or more refinement operations on the evaluated meters 102a-l, as will be described in more detail below. Refinement operations may include sorting the meters 102a-l that are classified as needing to be moved based on a level of certainty of the result. Various determinations of certainty may be used to refine the meter 102a-l needing to be moved/reassigned, as described herein.

The process 500 may then end at process block 518.

Upon the process 500 ending, the process 400 performs any final reconciliation operations necessary to make final adjustments at process block 410. Reconciliation operations may include verifying each single-phase transformer 104a-f within the system 100 has single-phase meters 102a-l of the same phase connected to it. For example, each transformer is given a phase class that is the representative of the phase mode of the meters 102a-l that are connected to it. From this phase class, appropriate verifications are made, such as moving meters 102a-l to transformers 104a-f to ensure that each transformer has a single representative phase class and that each meter is on a transformer 104a-f whose phase class matches the phase of the meter 102a-l.

In one example, if there are multiple phase representatives (i.e., meters of more than one phase) associated with a transformer 104a-f, the meters 102a-l are transferred to the closest transformer 104a-f having the same phase. Further, any meter 102a-l that is connected to a transformer 104a-f whose phase is not the same as the meter's phase is moved to the closest transformer that has the same phase as the meter 102a-l. In one example, the final reconciliation operations may include classifying individual meters 102a-l into one or more categories, such as meters 102a-l that do not need to be moved to a different transformer 104a-f, meters 102a-l that need to be moved to a specific transformer 104a-f, meters 102a-l that need to be moved but the correct transformer 104a-f is unknown, and meters 102a-l where it is unknown whether the meter needs to be moved. These classifications may be based on the data determined as described above in more detail. In some embodiments, there may be more of fewer classifications that are determined as required for a given application.

At process block 412, the process 400 may perform various refinement operations to further finally adjust the output of the process 400. Refinement operations may include sorting the meters 102a-l that are classified as needing to be moved based on a level of certainty of the result. Various determinations of certainty may be used to refine the meter 102a-l needing to be moved/reassigned.

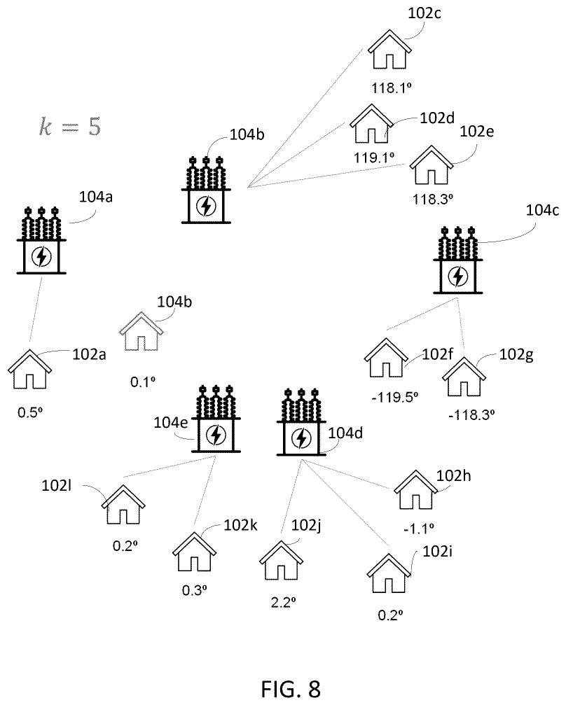

Upon the final adjustments being completed, the system 100 mapping is updated and finalized at process block 414. FIG. 8 illustrates a portion of the final updated map of the system 100.

Various features and advantages of the invention are set forth in the following claims.

What is claimed is:

1. A utility distribution system, comprising:
a plurality of electrical meters;
a plurality of transformers; and
a central utility controller, the central utility controller configured to:
receive an initial map of the plurality of electrical meters to their respective transformers;
receive data from the plurality of electrical meters;
execute an initial adjustment to the initial map by verifying that each electrical meter and transformer complies with a predefined constraint;
randomly analyze a first meter of the plurality of electrical meters to determine a first likely connection to a first transformer of the plurality of transformers; and
update a connection of the first meter to the first transformer in the initial map based on the determined first likely connection.

2. The system of claim 1, wherein the central utility controller is further configured to execute one or more similarity measures to determine the first likely connection.

3. The system of claim 1, wherein the central utility controller is further configured to:
iteratively randomly analyze an n+1 meter of the plurality of electrical meters to determine an n+1 likely connection to an n+1 transformer of the plurality of transformers; and
update the connection of the n+1 meter to the n+1 transformer based on the determined n+1 likely connection.

4. The system of claim 3, wherein the central utility controller is further configured to finalize the iterative random analysis in response to all n+1 meters being iteratively analyzed.

5. The system of claim 3, wherein a first statistic of a first data set of the received data from the first meter is correlated to the plurality of transformers, and the first meter is determined to have a likely connection to the first transformer by maximizing a correlation between the first statistic of the first data set and a second statistic of a second data set of a second meter known to be connected to the first transformer.

6. The system of claim 5, wherein the correlation is a Pearson correlation.

7. The system of claim 5, wherein the first data set includes a voltage magnitude.

8. The system of claim 5, wherein the first data set include a phase data.

9. The system of claim 1, wherein updating the initial map includes revising the connection between the first meter and the first transformer.

10. A method for verifying and revising a mapping of a utility distribution system, the method comprising:
receiving an initial map of a plurality of electrical meters and a plurality of transformers, wherein the initial map shows connections between the plurality of electrical meters and the plurality of transformers;
receiving data from the plurality of electrical meters;
executing an initial adjustment to the initial map by assigning each electrical meter of the plurality of electrical meters to a closest transformer of the plurality of transformers based on a distance between each electrical meter and the closest transformer;
randomly analyzing a first meter of the plurality of electrical meters to determine a first likely connection to a first transformer of the plurality of transformers; and
updating a connection of the first electrical meter to the first transformer in the initial map based on the determined first likely connection.

11. The method of claim 10, further comprising executing one or more similarity measures to determine the first likely connection.

12. The method of claim 10, further comprising:
iteratively randomly analyzing an n+1 electrical meter of the plurality of electrical meters to determine an n+1 likely connection to an n+1 transformer of the plurality of transformers; and
updating a connection of the n+1 electrical meter to the n+1 transformer in the initial map based on the determined n+1 likely connection.

13. The method of claim 12, wherein the process finalizes the iterative random analysis in response to all n+1 meters being iteratively analyzed.

14. The method of claim 12, wherein a first statistic of a first data set of the received data from the first meter is correlated to the plurality of transformers, and the first meter is determined to have a likely connection to the first transformer by maximizing a correlation between the first statistic of the first data set and a second statistic of a second data set of a second meter known to be connected to the first transformer.

15. The method of claim 14, wherein the correlation is a Pearson correlation.

16. The method of claim 14, wherein the first data set includes one or more of a voltage magnitude data set and a phase-data data set.

17. The method of claim 10, wherein updating the initial map includes revising the connection between the first electrical meter and the first transformer.

18. A utility distribution system, comprising:
a plurality of electrical meters;
a plurality of transformers; and
a central utility controller, the central utility controller configured to:
generate an initial map of the plurality of electrical meters to their respective transformers;
receive data from the plurality of electrical meters;
revise the initial map by assigning each meter of the plurality of electrical meters to a closest transformer of the plurality of transformers by distance;
determine a maximum number of meters per a first transformer of the plurality of transformers;
revise the initial map to verify that the first transformer of the plurality of transformers does not exceed the maximum number of meters connected thereto;
analyze a first electrical meter of the plurality of meters to determine a first likely connection to the first transformer of the plurality of transformers; and
update a connection of the first meter to the first transformer in the initial map based on the determined first likely connection.

19. The system of claim 18, wherein the maximum number of electrical meters per the first transformer of the plurality of transformers is determined based on determining whether a power consumption of a set of electrical meters of the plurality of meters indicated as connected to the first transformer of the plurality of transformers exceeds a nominal power of the first transformer.

20. The system of claim 18, wherein the central utility controller is further configured to:
iteratively randomly analyze an n+1 electrical meter of the plurality of electrical meters to determine an n+1 likely connection to an n+1 transformer of the plurality of transformers; and
update the connection of the n+1 electrical meter to the n+1 transformer in the initial map based on the determined n+1 likely connection.
